(19) United States
(12) Patent Application Publication
(10) Pub. No.: US 2025/0242388 A1
(43) Pub. Date: Jul. 31, 2025

(54) CLEANING DEVICES AND RELATED METHODS

(71) Applicant: ENTEGRIS, INC., Billerica, MA (US)

(72) Inventors: Kenneth Boblak, Reno, NV (US); Mark M. Stark, Saratoga, CA (US); Brian J. Green, Sparks, NV (US); Stevon L. Scott, Roseville, CA (US)

(21) Appl. No.: 19/040,391

(22) Filed: Jan. 29, 2025

Related U.S. Application Data
(60) Provisional application No. 63/626,350, filed on Jan. 29, 2024.

(51) Int. Cl. B08B 1/54

(52) U.S. Cl. CPC B08B 1/54

(57) ABSTRACT

Some embodiments of the present disclosure relate to a cleaning device including a first material having at least a first function; and a second material having at least a second function, wherein, when a probe card contacts the body, the cleaning device performs at least the first function and at least the second function.

### CROSS-REFERENCE TO RELATED APPLICATION

This application claims the benefit of and priority to U.S. Provisional Application No. 63/626,350 filed on Jan. 29, 2024, which is incorporated herein by reference in its entirety for all purposes.

### FIELD

The present disclosure relates to cleaning devices for probe cards and related methods.

### BACKGROUND

During wafer testing, the pins in the probe card array can become contaminated. This contamination results in higher contact resistance, leading to false negative tests and reduced first pass yield for integrated circuit manufacturers.

### SUMMARY

Some embodiments of the present disclosure relate to a cleaning device comprising: a body comprising: a first material having at least a first function; and a second material having at least a second function, wherein the cleaning device is adapted to perform at least the first function and the second function when a probe card contacts the body.

In some embodiments, the first material can be a structured layer and the second material can be a polymeric material.

In some embodiments, a portion of the patterned layer can be exposed through the second material.

In some embodiments, the patterned layer can include recessed surface portions arranged in a pattern.

In some embodiments, the body has a surface comprising the first material and the second material.

In some embodiments, the second material is located on the first material.

In some embodiments, the second material is embedded in the first material.

In some embodiments, the second material is dispersed in the first material.

In some embodiments, the second material is different from the first material.

In some embodiments, the body is supported by a substrate.

In some embodiments, the cleaning device is configured to perform at least the first function and at least the second function in one of a plurality of cleaning cycles.

In some embodiments, the first material, the second material, or combinations thereof comprises at least one of silicon oxide, diamond, silicon carbide, aluminum oxide, boron nitride, cerium oxide, zirconia, emery, garnet, quartz, boron carbide, tungsten carbide or combinations thereof.

In some embodiments, the first material, the second material, or combinations thereof comprises at least one of a silicone, a siloxane, an acrylate based polymer, a polyimide, a polyolefin, a polyurethane, an epoxy-based polymer, nylon, PEEK, a polyester, a polyether, polycarbonate, polysulfone, or a polymer comprising a vinyl group, a thiol group, or an amide group.

In some embodiments, the first material can be a silicon wafer, a silicon carbide wafer, an alumina wafer, or a glass substrate.

In some embodiments, the second material can be silicone, an acrylate based polymer, an epoxy based polymer, polyethylene terephthalate, or a polyimide.

In some embodiments, the first material can have a thickness of 1 μm to 1000 μm.

In some embodiments, the second material can have a thickness of 1 μm to 1000 μm.

In some embodiments, a surface area ratio of the first material to the second material can range from 100:1 to 1:100.

In some embodiments, the first material and/or the second material can include an abrasive component and a polymer binder.

In some embodiments, the first material can include an abrasive wafer.

In some embodiments, the first material and the second material include an acrylate based polymer, wherein the second material includes an abrasive material dispersed therein. The abrasive material can be silicon carbide.

Some embodiments of the present disclosure relate to a cleaning device including a body having a functional material having at least a first contact area for performing at least a first function a second contact are for performing at least a second function, wherein the cleaning device is adapted to perform at least the first function and at least the second function when a probe card contacts the body.

In some embodiments, the functional material consists of a single material.

In some embodiments, a thickness of the functional material in the first contact area ranges from 1 μm to 1000 μm.

In some embodiments, a thickness of the functional material in the second contact area ranges from 1 μm to 1000 μm.

In some embodiments, a first thickness of the functional material in the first contact area is greater than a second thickness of the functional material in the second contact area. In some embodiments, the functional material is modified in the first contact area and remains unmodified in the second contact area, wherein the first contact area differs in at least one mechanical property from the second contact area

Some embodiments of the present disclosure relate to a method of using a cleaning device including: contacting a probe card containing a plurality of pin elements with a cleaning device, wherein cleaning device comprises: a body comprising: a first material having at least a first function; and a second material having at least a second function, wherein the cleaning device performs at least the first function and at least the second function when a probe card contacts a surface of the body.

In some embodiments, the contacting comprises penetrating the cleaning device with a plurality of pin elements.

### BRIEF DESCRIPTION OF THE DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIGS. 1A-1B are schematic diagrams of A) a cross-section of a cleaning device and B) a plan view of the cleaning device, according to some embodiments.

FIG. 2 depicts a non-limiting embodiment of a cleaning device as described herein.

FIG. 3 depicts a non-limiting embodiment of a cleaning device as described herein.

FIG. 4 depicts a non-limiting embodiment of a cleaning device as described herein.

FIG. 5 depicts a non-limiting embodiment of a cleaning device as described herein.

FIGS. 6A-6C depict a non-limiting embodiment of a cleaning device as described herein.

FIGS. 7A-7B depict a non-limiting embodiment of the cleaning device as described herein.

FIGS. 8A-8B depict a non-limiting embodiment of a cleaning device as described herein.

FIG. 9 is a schematic showing the steps used to fabricate a cleaning device according to some embodiments as described herein.

FIG. 10 depicts a non-limiting embodiment of a method of using a cleaning device as described herein according to the various embodiments.

While the disclosure is amenable to various modifications and alternative forms, specifics thereof have been shown by way of example in the drawings and will be described in detail. It should be understood, however, that the intention is not to limit aspects of the disclosure to the particular illustrative embodiments described.

On the contrary, the intention is to cover all modifications, equivalents, and alternatives falling within the spirit and scope of the disclosure.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

Probe card testers are used for testing microelectronic devices, including semiconductor devices. During testing, probe cards are contaminated with metal oxides and other contaminants, resulting in errors (e.g., false negatives) during testing. For maintenance in conventional maintenance processes, probe cards undergo a multi-step process of lapping, polishing, cleaning, etc. The multi-step process requires at least two different devices. For example, during cleaning, the probe card (e.g., its pins) is inserted into a cleaning material to remove contaminants, such as, metal oxides, among others. The cleaning causes structural or mechanical damage to the pins of the probe card (e.g., the pins are flattened, rounded, etc.). To restore the pins of the probe card, the probe card (e.g., its pins) is inserted into a lapping material and/or a polishing material.

To improve process efficiency and performance relative to conventional processes for probe card cleaning, dual action cleaning devices are disclosed herein. The cleaning devices disclosed herein are capable of performing, among others, the polishing function and the lapping function, via a single device. Various configurations are described herein that contribute to dual-action feature of the probe card cleaning devices. The cleaning devices disclosed herein are useful for increasing production throughput and process efficiency. The various embodiments described herein provide cleaning devices that are customizable in function, efficiency, and use according to the particular circumstances of the probe card, among other things.

Some embodiments relate to a cleaning device useful for probe cards used in the manufacture and/or fabrication of devices, including semiconductor devices. In some embodiments, a cleaning device has a body. In some embodiments, the body includes a first material. In some embodiments, the first material has a first function. In some embodiments, the body includes a second material. In some embodiments, the second material has a second function. In some embodiments, the first material is different from the second material. In some embodiments, the first function is different from the second function. Non-limiting examples of the first function and/or the second function include, for example and without limitation, cleaning, including cleaning only along a vertical axis, polishing, lapping, restoring, forming, scrubbing, abrading, etc. In some embodiments, when a probe card contacts the body, the cleaning device performs at least the first function. In some embodiments the cleaning device also performs at the least the second function when a probe card contacts the body.

Various configurations for the relative locations of the first material and the second material are described herein. In some embodiments, the first material can be located adjacent to the second material. In some embodiments, the first material can abut the second material. In some embodiments, the first material can directly contact the second material. In some embodiments, the second material can be located on the first material. In some embodiments, the second material can be located on a plurality of protrusions between a plurality of recessed areas formed in the first material. In some embodiments, the second material can be embedded in the second material. In some embodiments, the second material can be dispersed in the first material. In some embodiments, the second material can be stacked on the first material.

In some embodiments, the second material can be located in a plurality of recesses formed in the first material. In some embodiments, with respect to the foregoing, the configuration of the first material and the second material are reversed. For simplicity, these are not repeated here.

According to various embodiments, the cleaning device body can include a plurality of recesses formed in a first material. As used herein, a recess is an area having a surface that is below another surface. The recesses, can be of any depth that is useful to facilitate the functionality of the cleaning device, described herein. In some cases, the recesses may define a plurality of raised portions adjacent the recesses. The plurality of recesses can include recessed areas for performing any one or more of the functions of the dual action cleaning devices disclosed herein. The outer perimeter of the recesses as viewed from the top of the cleaning device can have a variety of shapes. As a result, the recesses can have a variety of cross-sectional shapes when the device is viewed in cross-section. In some embodiments, the sidewalls of the recesses can be curved, straight, or angled. Additionally, a base or bottom wall of the recesses can be linear or curved. In some cases, the sidewalls of each recess can be continuously curved from a bottom wall of the recess in a direction towards a top outer edge of the recess. In other cases, the sidewalls of each of the recesses can have a stepped configuration such that the recesses have at least a first portion having a first depth and a second portion having a second depth, the depth being measured from a top outer edge of a recess to a base or bottom wall of the recess.

In some embodiments, the recess forming a plurality of recesses can include longitudinal strips of recessed areas formed in the body along an x or y axis such that the plurality of recesses defines a plurality of raised ridges with the recessed areas being located between the plurality of raised ridges. In some embodiments, the longitudinal strips of recessed areas can be linear. In some embodiments, the longitudinal strips of recessed areas can be curved. In some embodiments, the longitudinal strips of recessed areas can be wavy or can have a zig-zag configuration. In some embodiments, at least one of the first material, the second material, or any combination thereof, can be located in at least one of the recesses, on the plurality of raised ridges, or any combination thereof. In some embodiments, the recesses can include a polishing material and the plurality of raised ridges can include a lapping material

In some embodiments, the recesses and adjacent raised portions can define a pattern. The pattern can be a random pattern or an ordered pattern. In one embodiment, the recesses and adjacent raised portions can be arranged in a grid pattern, wherein the outer perimeter of the each of the recesses, when viewed from the top, defines a polygonal shape. In one embodiment, the outer perimeter of the each of the recesses can define a square, rectangle, or a hexagon. If the outer perimeter of the recesses defines a hexagon, the recesses and adjacent raised portions may define a honeycomb-like grid pattern.

In some embodiments, the recesses and adjacent raised portions can be arranged in a spotted pattern wherein the outer perimeter of each the recesses has a circular shape when viewed from the top and the sidewalls of each of the recesses are curved relative to a vertical axis extending from a top through a base of a recess. The base or bottom wall of such recesses can be curved or it can be linear. In some embodiments, at least one of the first material, the second material, or any combination thereof, can be located in at least one of the recesses, on the plurality of raised portions, or any combination thereof. In some embodiments, the recesses can include a polishing material and the plurality of raised portions can include a lapping material.

According to various embodiments, the recesses forming a plurality of recess can have a depth having any range or subrange between 10 microns and 1000 microns. Depth is measured from a top outer edge of a recess to a base or bottom wall of the recess. For example, in some embodiments, the plurality of recesses 35 have a depth ranging from 10 microns to 900 microns, 10 microns to 800 microns, 10 microns to 700 microns, 10 microns to 600 microns, 10 microns to 500 microns, 10 microns to 400 microns, 10 microns to 300 microns, 10 microns to 200 microns, 10 microns to 150 microns, 10 microns to 140 microns, 10 microns to 130 microns, 10 microns to 120 microns, 10 microns to 110 microns, 10 microns to 100 microns, 10 microns to 90 microns, 10 microns to 80 microns, 10 microns to 70 microns, 10 microns to 60 microns, 10 microns to 50 microns, 10 microns to 40 microns, 10 microns to 30 microns, 10 microns to 20 microns, 20 microns to 150 microns, 30 microns to 150 microns, 40 microns to 150 microns, 50 microns to 150 microns, 60 microns to 150 microns, 70 microns to 150 microns, 80 microns to 150 microns, 90 microns to 150 microns, 100 microns to 150 microns, 110 microns to 150 microns, 120 microns to 150 microns, 130 microns to 150 microns, or 140 microns to 150 microns.

The configuration, arrangement, depth, and/or shape of the recesses is not particularly limited and can include other variations, without departing the scope of this disclosure. In some embodiments, the body of a cleaning device may not include a recess or plurality of recesses.

In some embodiments of a cleaning device as described herein, the recesses forming a plurality of recesses can be formed in the first material. A second material may be disposed or located in the recesses formed in the first material. A thickness of the second material located in the recesses, as described herein, may be equal to or less than a depth of the plurality of recesses. In some embodiments, a thickness of the second material disposed in the recesses can have any range or subrange between 10 microns and 1000 microns. For example, in some embodiments, the second material can have a thickness ranging from 10 microns to 900 microns, 10 microns to 800 microns, 10 microns to 700 microns, 10 microns to 600 microns, 10 microns to 500 microns, 10 microns to 400 microns, 10 microns to 300 microns, 10 microns to 200 microns, 10 microns to 150 microns, 10 microns to 140 microns, 10 microns to 130 microns, 10 microns to 120 microns, 10 microns to 110 microns, 10 microns to 100 microns, 10 microns to 90 microns, 10 microns to 80 microns, 10 microns to 70 microns, 10 microns to 60 microns, 10 microns to 50 microns, 10 microns to 40 microns, 10 microns to 30 microns, 10 microns to 20 microns, 20 microns to 150 microns, 30 microns to 150 microns, 40 microns to 150 microns, 50 microns to 150 microns, 60 microns to 150 microns, 70 microns to 150 microns, 80 microns to 150 microns, 90 microns to 150 microns, 100 microns to 150 microns, 110 microns to 150 microns, 120 microns to 150 microns, 130 microns to 150 microns, or 140 microns to 150 microns.

In some embodiments of a cleaning device as described herein, the functional surface of a cleaning device (e.g., the top surface) can be characterized by the surface area of the first material, which performs a first function (e.g., lapping), and the surface area of the second material, which performs a second function (e.g. polishing, cleaning, etc.). In some embodiments, a surface area of the first material is 5% to 100% of the total surface area of the functional surface (e.g., top surface) of the cleaning device, or any range or subrange between 5% and 100%. For example, in some embodiments, a surface area of the first material is 5% to 95%, 5% to 90%, 5% to 85%, 5% to 80%, 5% to 75%, 5% to 70%, 5% to 65%, 5% to 60%, 5% to 55%, 5% to 50%, 5% to 45%, 5% to 40%, 5% to 35%, 5% to 30%, 5% to 25%, 5% to 20%, 5% to 15%, 5% to 10%, 10% to 95%, 15% to 95%, 20% to 95%, 25% to 95%, 30% to 95%, 35% to 95%, 40% to 95%, 45% to 95%, 50% to 95%, 55% to 95%, 60% to 95%, 65% to 95%, 70% to 95%, 75% to 95%, 80% to 95%, 85% to 95%, or 90% to 95% of the total surface area of the functional surface (e.g., top surface) of the cleaning device.

In some embodiments, a surface area of the second material is 5% to 100% of the total surface area of the functional surface (e.g., top surface) of the cleaning device, or any range or subrange between 5% and 100%. For example, in some embodiments, a surface area of the second material is 5% to 95%, 5% to 90%, 5% to 85%, 5% to 80%, 5% to 75%, 5% to 70%, 5% to 65%, 5% to 60%, 5% to 55%, 5% to 50%, 5% to 45%, 5% to 40%, 5% to 35%, 5% to 30%, 5% to 25%, 5% to 20%, 5% to 15%, 5% to 10%, 10% to 95%, 15% to 95%, 20% to 95%, 25% to 95%, 30% to 95%, 35% to 95%, 40% to 95%, 45% to 95%, 50% to 95%, 55% to 95%, 60% to 95%, 65% to 95%, 70% to 95%, 75% to 95%, 80% to 95%, 85% to 95%, or 90% to 95% of the total surface area of the functional surface (e.g., top surface) of the cleaning device.

In some embodiments, the first material 110 can have a thickness of 1 μm to 1000 μm or any range or subrange therebetween. For example, in some embodiments, the first material 110 can have a thickness of 1 μm to 950 μm, 1 μm to 900 μm, 1 μm to 850 μm, 1 μm to 800 μm, 1 μm to 750 μm, 1 μm to 700 μm, 1 μm to 650 μm, 1 μm to 600 μm, 1 μm to 550 μm, 1 μm to 500 μm, 1 μm to 450 μm, 1 μm to 400 μm, 1 μm to 350 μm, 1 μm to 300 μm, 1 μm to 250 μm, 1 μm to 200 μm, 1 μm to 150 μm, 1 μm to 100 μm, or 1 μm to 50 μm. In other embodiments, the first material 110 has a thickness of 50 μm to 1000 μm, 100 μm to 1000 μm, 150 μm to 1000 μm, 200 μm to 1000 μm, 250 μm to 1000 μm, 300 μm to 1000 μm, 350 μm to 1000 μm, 400 μm to 1000 μm, 450 μm to 1000 μm, 500 μm to 1000 μm, 550 μm to 1000 μm, 600 μm to 1000 μm, 650 μm to 1000 μm, 700 μm to 1000 μm, 750 μm to 1000 μm, 800 μm to 1000 μm, 850 μm to 1000 μm, 900 μm to 1000 μm, or 950 μm to 1000 μm.

In some embodiments, the second material 120 can have a thickness of 1 μm to 1000 μm or any range or subrange therebetween. For example, in some embodiments, the second material 120 can have a thickness of 1 μm to 950 μm, 1 μm to 900 μm, 1 μm to 850 μm, 1 μm to 800 μm, 1 μm to 750 μm, 1 μm to 700 μm, 1 μm to 650 μm, 1 μm to 600 μm, 1 μm to 550 μm, 1 μm to 500 μm, 1 μm to 450 μm, 1 μm to 400 μm, 1 μm to 350 μm, 1 μm to 300 μm, 1 μm to 250 μm, 1 μm to 200 μm, 1 μm to 150 μm, 1 μm to 100 μm, or 1 μm to 50 μm. In other embodiments, the second material 120 has a thickness of 50 μm to 1000 μm, 100 μm to 1000 μm, 150 μm to 1000 μm, 200 μm to 1000 μm, 250 μm to 1000 μm, 300 μm to 1000 μm, 350 μm to 1000 μm, 400 μm to 1000 μm, 450 μm to 1000 μm, 500 μm to 1000 μm, 550 μm to 1000 μm, 600 μm to 1000 μm, 650 μm to 1000 μm, 700 μm to 1000 μm, 750 μm to 1000 μm, 800 μm to 1000 μm, 850 μm to 1000 μm, 900 μm to 1000 μm, or 950 μm to 1000 μm

An overall thickness of a cleaning device, as described herein according to the various embodiments, can range from 10 microns to 2000 microns, or any range or subrange between 10 microns and 2000 microns. For example, in some embodiments, the overall thickness of a cleaning device can range from 10 microns to 1000 microns, 10 to 900 microns, 10 to 800 microns, 10 microns to 700 microns, 10 microns to 600 microns, 10 microns to 500 microns, 10 microns to 400 microns, 10 microns to 300 microns, 10 microns to 250 microns, 10 microns to 240 microns, 10 microns to 230 microns, 10 microns to 210 microns, 10 microns to 210 microns, 10 microns to 200 microns, 10 microns to 190 microns, 10 microns to 180 microns, 10 microns to 170 microns, 10 microns to 160 microns, 10 microns to 150 microns, 10 microns to 140 microns, 10 microns to 130 microns, 10 microns to 110 microns, 10 microns to 110 microns, 10 microns to 100 microns, 10 microns to 90 microns, 10 microns to 80 microns, 10 microns to 70 microns, 10 microns to 60 microns, 10 microns to 50 microns, 10 microns to 40 microns, 10 microns to 30 microns, 30 microns to 250 microns, 40 microns to 250 microns, 50 microns to 250 microns, 60 microns to 250 microns, 70 microns to 250 microns, 80 microns to 250 microns, 90 microns to 250 microns, 100 microns to 250 microns, microns to 250 microns, 110 microns to 250 microns, 120 microns to 250 microns, 130 microns to 250 microns, 140 microns to 250 microns, 150 microns to 250 microns, 160 microns to 250 microns, 170 microns to 250 microns, 180 microns to 250 microns, 190 microns to 250 microns, 200 microns to 250 microns, 210 microns to 250 microns, 220 microns to 250 microns, 230 microns to 250 microns, or 240 microns to 250 microns. In some embodiments, the overall thickness is measured in the thickest part of the cleaning device. In some embodiments, the overall thickness does not include a support or substrate on which the first material and/or second material is located.

According to various embodiments, the first material, the second material, and or combinations thereof can include at least one of a thermoplastic polymer, a thermoset polymer, a vitrimer polymer, a biopolymer, a biodegradable polymer, or any combination thereof. In some embodiments, the first material, the second material, or combinations thereof can include at least one of silicon oxide, diamond, silicon carbide, aluminum oxide, boron nitride, mullite, fumed silica, cerium oxide, zirconia, emery, garnet, quartz, boron carbide, tungsten carbide, or combinations thereof. In some embodiments, the first material, the second material, or combinations thereof can include a polymeric material. In some embodiments, the first material, second material and/or combinations thereof can include at least one of a silicone, a siloxane, an acrylate based polymer, a polyimide, a polyolefin, a polyurethane, an epoxy-based polymer, nylon, PEEK, a polyester, a polyether, polycarbonate, polysulfone, or a polymer comprising a vinyl group, a thiol group, or an amide group.

In some embodiments, the first material can be a silicon wafer, a silicon carbide wafer, an alumina wafer, a glass substrate, or the like, depending on the application.

In some embodiments, the second material can be silicone, an acrylate based polymer, an epoxy based polymer, polyethylene terephthalate, or polyimide, depending on the application.

In some embodiments, the first material and the second material can be different. In some embodiments, the first material can be a silicon wafer, a silicon carbide wafer, an alumina wafer, a glass substrate, or the like and the second material can be a polymeric material such as described herein. In some embodiments, the second material can be silicone, an acrylate based polymer, an epoxy based polymer, polyethylene terephthalate, or polyimide.

In some embodiments, the first material can include an abrasive component and a polymer binder. In some embodiments, the second material can include an abrasive component and a polymer binder. In some embodiments, the first material, the second material, or a combination of the first material and the second material can include abrasive component. In some embodiments, the abrasive component can be a plurality of abrasive particles having a Mohs hardness value greater than 6 and a d50 (center point of size distribution) ranging from 0.1 to 50 μm.

In some embodiments, the first material can be an abrasive substrate or wafer. The abrasive substrate or wafer can have a Mohs hardness value greater than 6.

A cleaning device body including the first and the second material, as described herein according to the various embodiments, can be supported on a substrate. In some embodiments, the substrate can be formed from polyethylene terephthalate or a polyimide or the substrate can be any one of a silicon wafer, a silicon carbide wafer, an alumina wafer, a glass substrate, and/or the like.

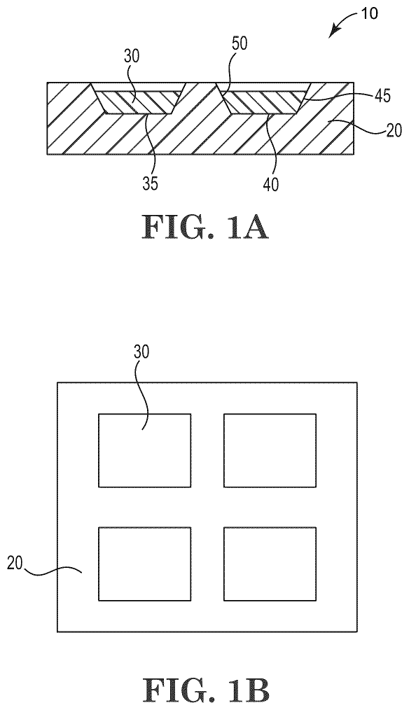

FIGS. 1A-1B are schematic diagrams of a cross-sectional view (FIG. 1A) and a plan view (FIG. 1B) of a cleaning device 10, according to one illustrative embodiment. As shown in FIG. 1A, cleaning device 10 includes a first layer 20 and a second layer 30 located on the first layer 20. At least a portion of the first layer 20 is exposed through the second layer 30. The first layer 20 can include a first material having a first function. The second layer 30 can include a second material having a second function. Non-limiting examples of the first function and/or the second function include, for example and without limitation, cleaning, including cleaning only along a vertical axis, polishing, lapping, restoring, forming, scrubbing, abrading, etc. The first function and the second function may be different. In some embodiments, for example, the first function is at least a lapping function and the second function is at least a polishing function. In some embodiments, the first function can have a function in addition to the lapping function. Similarly, the second function can have a function in addition to the polishing function.

As shown in FIGS. 1A and 1B, cleaning device 10 includes a plurality of recesses 35 formed in the first material of the first layer 20. As shown in FIG. 1B, the recesses 35 are arranged in a grid pattern. The second material of the second layer 30 is located in the recesses 35 formed in the first layer 20. As shown in FIG. 1A, the recesses 35 have a linear base 40 and angled sidewalls 45, 50. The angled sidewalls 45, 50 are angled outwards such that the sidewalls 45, 50 are visible when viewing cleaning device 10 from a perspective or a top plan view. The angle at which the sidewalls 45, 50 are angled is not particularly limited and can range from upright or vertical, to less than 90 degrees from the vertical position in the outward direction. In other embodiments, the angled walls 45, 50 can be angled inward, such that the surfaces of the sidewalls are not visible from a perspective or a plan view.

It will be appreciated that the recesses 35 can have any of a number of different cross-sectional configurations in addition to the cross-sectional configuration depicted in FIG. 1A, without departing from the scope of the present disclosure. It will also be appreciated that the recesses 35 can be arranged in patterns other than a grid pattern, including any of those disclosed herein. In addition, although shown with same or similar angled sidewalls 45, 50, it will further be appreciated that each of the sidewalls and base of the cleaning device 10 may be different, without departing from the scope of this disclosure. For example, in some embodiments, at least two of the walls of the recesses 35 can be angled at different angles. In some embodiments, at least two of the recesses 35 can have different cross-sectional configurations. For example, in some embodiments, the cleaning device 10 may further comprise a recess having curved side walls and/or a curved base, in addition to the recesses depicted in FIG. 1A.

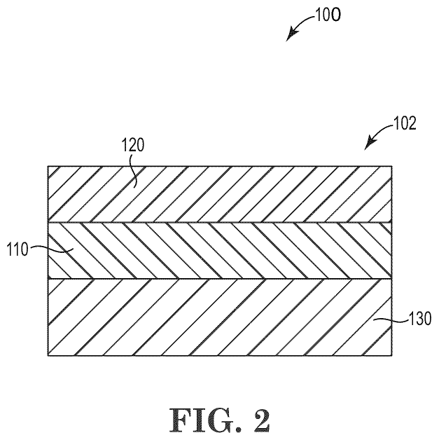

FIGS. 2-5 are non-limiting embodiments of a cleaning device 10 including a first material and a second material each having a different function, as described herein. As shown in FIGS. 2-5, cleaning device 100 includes a body 102 which includes a first material 110 having at least a first function and a second material 120 having at least a second function. The first function can be a lapping function and the second function can be a polishing function. When a probe card contacts the body 102, the cleaning device 100 performs at least the first function and at least the second function. In some embodiments, the cleaning device 100 is configured to perform at least the first function and at least the second function in one of a plurality of cleaning cycles. In some embodiments, the body 102 can be supported by a substrate 130, as shown in FIGS. 2-5.

In some embodiments, the first material 110 forms a patterned layer and the second material 120 can be a polymer layer. In some embodiments, a portion of the patterned layer can be exposed through the second material 120. In some embodiments, the first material 110 can include a plurality of recessed surface portions arranged in a pattern, as described herein.

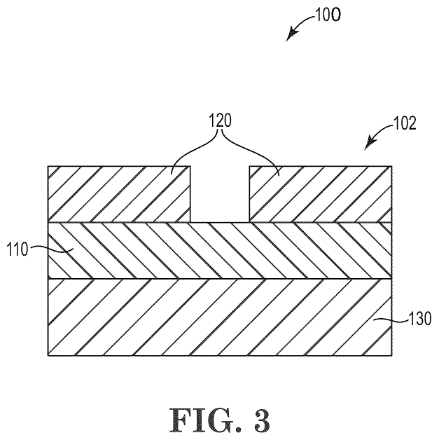

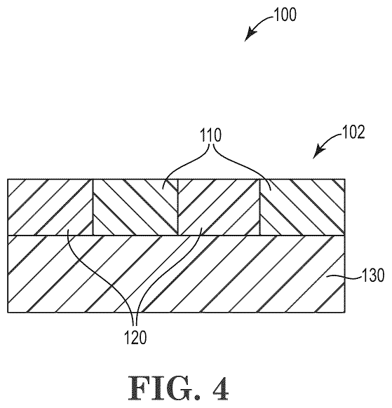

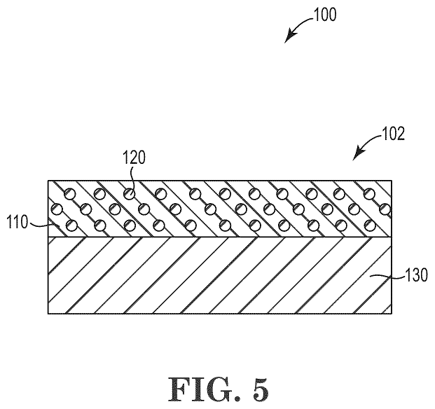

In some embodiments, as shown in the illustrative examples of FIGS. 2-5, the body 102 has a surface comprising the first material 110 and/or the second material 120. As seen in FIG. 2, the second material 120 may be disposed over and in contact with the first material 110. As seen in FIG. 3, the second material 120 may be disposed on the first material 110 wherein the first material 110 is exposed through a gap in the second material 120. As seen in FIG. 4, the first material 110 may be located adjacent the second material 120 such that a surface of the first material 110 is coplanar with a surface of the second material. As seen in FIG. 5, the second material 120 may be embedded in the first material. Additionally, as seen in FIG. 5, the second material 120 may be dispersed in the first material 110.

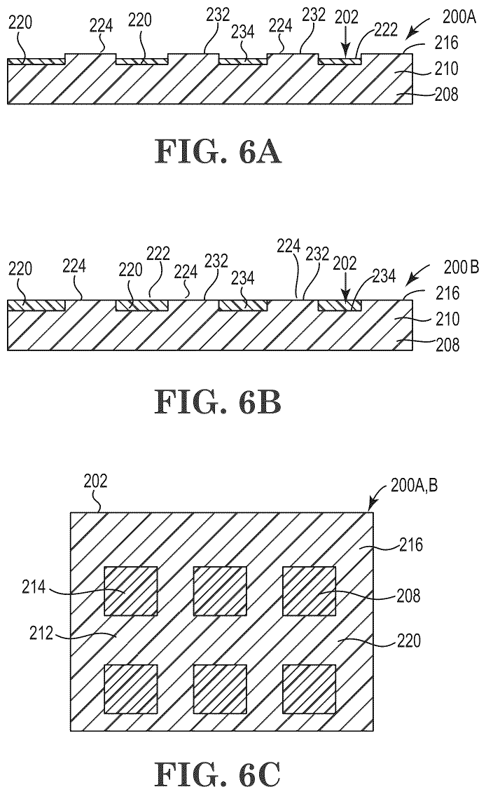

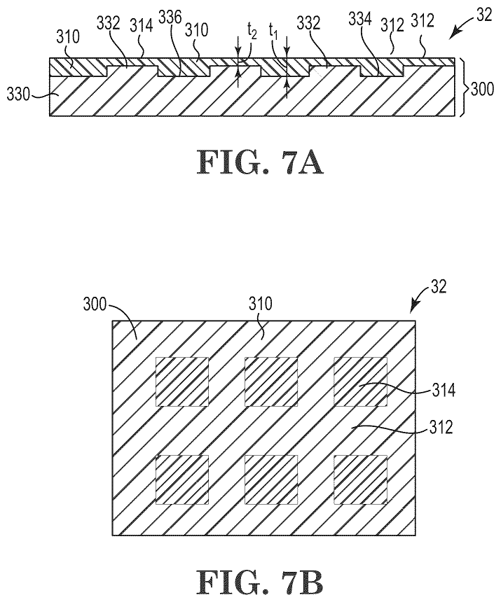

FIGS. 6A-6C are schematic diagrams of a cross-section of a cleaning device 200A, 200B (FIGS. 6A and 6B) and a top plan view of a cleaning device 200 (FIG. 7C), according to some embodiments. As shown in FIGS. 6A and 6B, cleaning device 30 includes a body 202 having a second material 220 disposed over a base 210 including a first material 208. The base 210 can be structured or patterned such that it is a structured base and can include a plurality of raised portions 232 and a plurality of recessed portions 234. The raised portions 232 can have any shape including a polygonal or circular shape. For example, the raised portions 232 may be square, circular, hexagonal, octagonal, but not limited to these. In some embodiments the raised portions 232 may be a plurality of raised ridges defining the plurality of recessed portions 234. The recessed portions 234 can be configured as trenches or channels disposed between the raised portions 2332. In some embodiments the plurality of raised portions 232 and recessed portions 234 may define a grid pattern, as described herein. In various embodiments, the sidewalls of the recessed portions 234 can be sloped or angled (not shown). In one embodiment, the sidewalls of recessed portions 234 are angled outward from a central axis extending through the recessed portions 234 from a top outer edge of the recessed portion through a bottom wall of the recessed portion.

As shown in the illustrative embodiment of FIGS. 6A and 6B, the second material 220 can be disposed over the base 210 including the first material 208 such that the functional surface 216 (including top surfaces 222, 224) of the cleaning device 20 includes both the first material 208 of the base 210 and the second material 220. In one embodiment, as shown in FIG. 6A, a top surface 222 of the second material 220 is recessed from a top surface 224 of the first material 208. In another embodiment, as shown in FIG. 6B, a top surface 222 of the second material 220 is coplanar with a top surface 224 of the first material 208 of the structured base 210. In some embodiments, an exposed surface area ratio of the first material 110 to the second material 120 can be 100:1 to 1:100.

In some embodiments, the exposed regions 212 of the first material 208 can provide a first function and the exposed regions 214 of the second material 220 can provide a second function. Non-limiting examples of the first function and/or the second function include, for example and without limitation, cleaning, including cleaning only along a vertical axis, polishing, lapping, restoring, forming, scrubbing, abrading, etc. In some embodiments, the first material 208 of the structured base 210 provides a lapping function and the second material 220 provides polishing function. In some embodiments, the first material 208 of the structured base 210 provides a lapping function and the second material 220 provides a cleaning function.

FIGS. 7A and 7B are schematic diagrams of a cleaning device 32 according to an illustrative embodiment of the disclosure. FIG. 7A is a cross-sectional view and FIG. 7B is a top plan view of a cleaning device 32. As shown in FIGS. 7A and 7B, cleaning device 32 includes a body 300 having a functional material 310 disposed over a base 330 such that the exposed surface of the cleaning device 32 includes only the functional material 310. In other words, one hundred percent of the functional surface area (e.g., top surface) of the cleaning device 32 includes the functional material 310. The functional material 310 includes at least a first contact area 312 area for performing a first function a second contact area 314 for performing a second function. Non-limiting examples of the first function and/or the second function include, for example and without limitation, cleaning, including cleaning only along a vertical axis, polishing, lapping, restoring, forming, scrubbing, abrading, etc. In some embodiments, the first function is a lapping function and the second function is a polishing function. In some embodiments, the first function is a lapping function and the second function is a cleaning function.

The base 330 can be a structured or patterned and can include a plurality of raised portions 332 and a plurality of recessed portions 334. The raised portions 332 can have any form including polygonal or circular shapes. For example, the raised portions 332 may be square, circular, hexagonal, octagonal, but not limited to these. In some embodiments the raised portions 332 may be a plurality of raised ridges defining a plurality or recesses 334 therebetween. In some embodiments the plurality of raised portions 332 and recesses 334 may define a grid pattern. In various embodiments, the sidewalls of the recessed portions can be angled or covered (not shown), as described herein. The base or bottom wall 336 of the recesses can be linear, as shown, or it can be curved.

In some embodiments, as shown in FIG. 7A, the functional material 310 may be disposed over the structured base 330 such that it completely fills the recesses 334 such that a top surface of the functional material 310 located in the recesses 334 is co-planar with a top surface of the functional material 310 located over the raised portions 332, as shown. In some embodiments, the functional material 310 may not completely fill the recessed portions 334, but still extend over a top surface of the raised portions 332 of the structured base 330 such that substantially all of the functional surface area of the cleaning device 32 includes the functional material 310. For example, the functional material 310 may be disposed over the structured base 330 such that it contacts the top surfaces of the raised portions 332 as well the sidewalls and bottom wall of the recessed portions 334 but does not completely fill the recessed portions 334.

In some embodiments, a first thickness t₁ of the functional material 310 in the first contact area 312 is greater than a second thickness t₂ of the functional material 310 in the second contact area 314 such that a hardness of the first contact area 312 is less than a hardness of the second contact area 314. In some embodiments, a ratio of a thickness t₁ of the functional material 310 in the first contact area 314 to a thickness t₂ of the functional material 310 in the second contact area 312 ranges from 100:1 to 1:100 or any subrange therebetween. In some cases, a thickness of the functional material 310 in a recess 334 may be less than 50% of a depth of the recess, less than 25% of a depth of a recess, and more particularly, less than 10% of a depth of a recess.

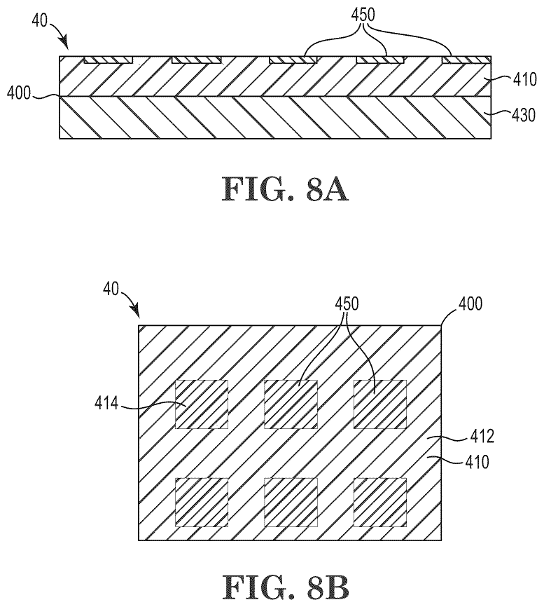

FIGS. 8A and 8B are schematic diagrams of a cleaning device 40 in accordance with another embodiment of the disclosure. Cleaning device 40 includes a functional material 410 disposed over and in contact with a substrate 430 such that the exposed surface of cleaning device 42 includes only the functional material 410. In other words, one hundred percent of the functional surface area (e.g., top surface) of the cleaning device 42 includes the functional material 410. In some embodiments, selected regions 450 of the functional material 410 can be modified such that the selected regions 450 perform a function different from regions of unmodified functional material 410. In some cases, the selected regions 450 can be modified such that they perform a first function and the unmodified functional material 410 surrounding the selected regions 450 perform a second function. Non-limiting examples of the first function and/or the second function include, for example and without limitation, cleaning, including cleaning only along a vertical axis, polishing, lapping, restoring, forming, scrubbing, abrading, etc. In some embodiments, the first function can be at least a lapping function and the second function can be at least a polishing function.

The selected regions 450 can be modified such that they have difference in mechanical properties from the surrounding unmodified functional material 410. This difference in mechanical properties provides the differences functionality (i.e., first and second functions) of the unmodified functional material 410 and the selected regions 450. For example, the second regions 450 may differ in hardness, tensile modulus, and/or stiffness from the unmodified functional material 410. In some embodiments, the selected regions 410 can be modified such that they have a greater hardness, tensile modulus, and/or stiffness than the surrounding unmodified functional material 410.

The select regions 450 of the functional material 410 may be modified by the application of a surface modification treatment, heat, radiation, mechanical stress, electric field, magnetic field, and the like.

In some embodiments, a surface area of the unmodified functional material 410 is 5% to 95% of the total surface area of the functional surface (e.g., top surface) of the cleaning device 40, or any range or subrange between 5% and 95%. For example, in some embodiments, a surface area of the unmodified functional material 410 is 5% to 95%, 5% to 90%, 5% to 85%, 5% to 80%, 5% to 75%, 5% to 70%, 5% to 65%, 5% to 60%, 5% to 55%, 5% to 50%, 5% to 45%, 5% to 40%, 5% to 35%, 5% to 30%, 5% to 25%, 5% to 20%, 5% to 15%, 5% to 10%, 10% to 95%, 15% to 95%, 20% to 95%, 25% to 95%, 30% to 95%, 35% to 95%, 40% to 95%, 45% to 95%, 50% to 95%, 55% to 95%, 60% to 95%, 65% to 95%, 70% to 95%, 75% to 95%, 80% to 95%, 85% to 95%, or 90% to 95% of the total surface area of the top surface of the cleaning device 40.

In some embodiments, a surface area of the selected areas 450 is 5% to 95% of the total surface area of the functional surface (e.g., top surface) of the cleaning device 100, or any range or subrange between 5% and 95%. For example, in some embodiments, a surface area of the selected areas 450 is 5% to 95%, 5% to 90%, 5% to 85%, 5% to 80%, 5% to 75%, 5% to 70%, 5% to 65%, 5% to 60%, 5% to 55%, 5% to 50%, 5% to 45%, 5% to 40%, 5% to 35%, 5% to 30%, 5% to 25%, 5% to 20%, 5% to 15%, 5% to 10%, 10% to 95%, 15% to 95%, 20% to 95%, 25% to 95%, 30% to 95%, 35% to 95%, 40% to 95%, 45% to 95%, 50% to 95%, 55% to 95%, 60% to 95%, 65% to 95%, 70% to 95%, 75% to 95%, 80% to 95%, 85% to 95%, or 90% to 95% of the total surface area of the cleaning device 40.

In some embodiments, a surface area ratio of the unmodified functional material 410 to the selected areas 450 is 100:1 to 1:100.

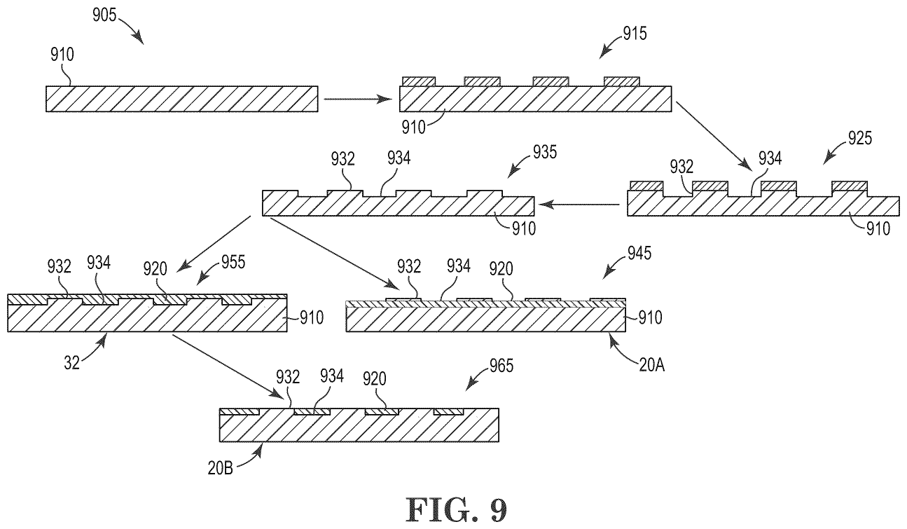

FIG. 9 is a schematic showing the steps used to fabricate a cleaning device such as cleaning devices 20A, 20B, and 32 described above with reference to FIGS. 6A-7B. As evident from FIG. 9, the cleaning devices 20A, 20B, and 30 can be fabricated using a photolithographic process including a wet/dry etch step and a mechanical planarization step. A substrate or base 910 comprised of a first material is provided at step 905. The base 910 can include any one of the materials as described herein including, but not limited to a bulk polymer, a silicon wafer, a silicon carbide wafer, an alumina wafer, a glass substrate, and/or the like. The base 910 can patterned using a photolithographic process in which a photoresist is applied to the substrate 910 as depicted at step 915. At step 925, wet or dry etch process is used to remove material from the base 910 to form a plurality of raised portions 932 and a plurality of recesses 934. The photoresist material is then removed at step 935 leaving behind a structured base 910. The structured base 910 can be coated with a second material 920 as described herein. In one embodiment, depicted at step 945, the structured base 910 can be coated with a second material such that the second material begins to fill the recesses 934 between the raised portions 932 to form a body of a cleaning device, such as cleaning device 20A described herein with reference to FIG. 6A. In some embodiments, at step 955, the second material can continue to be applied to the structured base 910 until the second material form a top surface of a body of a cleaning device, such as cleaning device 30 described herein with reference to FIGS. 7A and 7B. At step 965, the device 30 can be subjected to mechanical planarization to produce a body of a cleaning device such as cleaning device 20B described herein with reference to FIG. 6B.

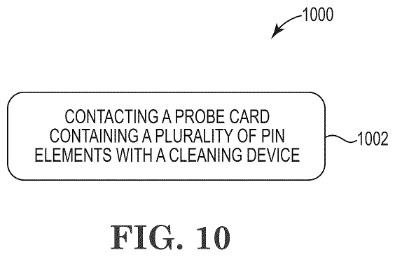

FIG. 10 depicts a non-limiting embodiment of the method described herein. As shown in FIG. 10, the method 1000 of using a cleaning device, includes step 1002 of contacting a probe card containing a plurality of pin elements with a cleaning device, wherein the cleaning device includes a body. The cleaning device may be any one of the cleaning devices as described herein with reference to FIGS. 2-8B. When a probe card contacts the surface of the body of a cleaning device such as one of the cleaning devices described herein according to the various embodiments, the cleaning device performs at least the first function and at least the second function. In some embodiments, the contacting comprises penetrating the cleaning device with a plurality of pin elements.

### ASPECTS

Various Aspects are described below. It is to be understood that any one or more of the features recited in the following Aspect(s) can be combined with any one or more other Aspect(s).

Aspect 1. A cleaning device comprising:
a body comprising:
   a first material having at least a first function; and
   a second material having at least a second function,
wherein, the cleaning device is adapted to perform at least the first function and the second function when a probe card contacts the body.

Aspect 2. The cleaning device according to Aspect 1, wherein the first material is a patterned layer and the second material comprises a polymer layer.

Aspect 3. The cleaning device of according to any one of Aspects 1-2, wherein a portion of the patterned layer is exposed through the second material.

Aspect 4. The cleaning device of according to any one of Aspects 1-3, wherein the patterned layer comprises recessed surface portions arranged in a pattern.

Aspect 5. The cleaning device according to any one of Aspects 1-4, wherein the body has a surface comprising the first material and the second material.

Aspect 6. The cleaning device according to any one of Aspects 1-5, wherein the first material is adjacent to the second material.

Aspect 7. The cleaning device according to any one of Aspects 1-6, wherein the second material is located on the first material.

Aspect 8. The cleaning device according to any one of Aspects 1-7, wherein the second material is embedded in the first material.

Aspect 9. The cleaning device according to any one of Aspects 1-8, wherein the second material is dispersed in the first material.

Aspect 10. The cleaning device according to any one of Aspects 1-9, wherein the second material is different from the first material.

Aspect 11. The cleaning device according to any one of Aspects 1-10, wherein the body is supported by a substrate.

Aspect 12. The cleaning device according to any one of Aspects 1-11, wherein the cleaning device is configured to perform at least the first function and at least the second function in one of a plurality of cleaning cycles.

Aspect 13. The cleaning device according to any one of Aspects 1-12, wherein the first material, the second material, or combinations thereof comprises at least one of silicon oxide, diamond, silicon carbide, aluminum oxide, boron nitride, cerium oxide, zirconia, emery, garnet, quartz, boron carbide, tungsten carbide or combinations thereof.

Aspect 14. The cleaning device according to any one of Aspects 1-13, wherein the first material, the second material, or combinations thereof comprises at least one of a silicone, a siloxane, an acrylate based polymer, a polyimide, a polyolefin, a polyurethane, an epoxy-based polymer, nylon, PEEK, a polyester, a polyether, polycarbonate, polysulfone, or a polymer comprising a vinyl group, a thiol group, or an amide group.

Aspect 15. The cleaning device according to any one of Aspects 1-14, wherein the first material has a thickness of 1 μm to 1000 μm.

Aspect 16. The cleaning device according to any one of Aspects 1-15, wherein the second material has a thickness of 1 μm to 1000 μm.

Aspect 17. The cleaning device according to any one of Aspects 1-16, wherein a surface area ratio of the first material to the second material is 100:1 to 1:100.

Aspect 18. The cleaning device according to any one of Aspects 1-17, wherein the first material comprises an abrasive component and a polymer binder.

Aspect 19. The cleaning device according to any one of Aspects 1-18, wherein the second material comprises an abrasive component and a polymer binder.

Aspect 20. A method of using a cleaning device:
contacting a probe card containing a plurality of pin elements with a cleaning device, wherein cleaning device comprises:
   a body comprising:
      a first material having at least a first function; and
      a second material having at least a second function,
   wherein, when a probe card contacts a surface of the body, the cleaning device performs at least the first function and at least the second function.

Aspect 21. The method of according to Aspect 20, wherein the contacting comprises penetrating the cleaning device with a plurality of pin elements.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. A cleaning device configured to perform at least a first function and a second function in a plurality of cleaning cycles, the cleaning device comprising:
a body comprising:
a base comprising a first material for performing a first function; and
a second material for performing a second function disposed over the base,
wherein the cleaning device is adapted to perform at least the first function and the second function when a probe card contacts the body.

2. The cleaning device of claim 1, wherein the base is a structured base and comprises a plurality of recessed surface portions arranged in a pattern.

3. The cleaning device of claim 1, wherein the body has a functional top surface comprising the first material and the second material, wherein the first material provides at least the first function.

4. The cleaning device of claim 3, wherein the first function is a lapping function and the second function is a polishing function.

5. The cleaning device of claim 3, wherein a top surface of the first material is coplanar with a top surface of the second material.

6. The cleaning device of claim 3, wherein a top surface of the second material is recessed relative to a top surface of the first material.

7. The cleaning device of claim 3, wherein the first material comprises a silicon wafer, a silicon carbide wafer, an alumina wafer, or a glass substrate, and wherein the first material is different than the second material.

8. The cleaning device of claim 3, wherein the first material comprises silicone, an acrylate-based polymer, an epoxy-based polymer, polyethylene terephthalate, or polyimide.

9. The cleaning device of claim 8, wherein the second material comprises silicone, an acrylate-based polymer, an epoxy-based polymer, polyethylene terephthalate, or polyimide and an abrasive material dispersed therein.

10. The cleaning device of claim 9, wherein the abrasive material comprises silicon carbide.

11. The cleaning device of claim 1, wherein a functional surface area ratio of the second material to the first material is 100:1 to 1:100.

12. The cleaning device of claim 1, wherein the base is supported by a substrate.

13. The cleaning device of claim 2, wherein the second material is disposed over the structured base comprising the first material such that one hundred percent of a functional surface area of the body comprises the second material.

14. The cleaning device of claim 13, wherein the second material comprises at least a first contact area for performing a first function and a second contact area for performing at least a second function.

15. The cleaning device of claim 14, wherein the first function is a lapping function and the second function is a polishing function.

16. The cleaning device of claim 13, wherein a first thickness t₁ of the least one first contact area is greater than a second thickness t₂ of the at least one second contact area.

17. The cleaning device of claim 13, wherein a hardness of the at least one second contact area is greater than a hardness of the at least one first contact area.

18. The cleaning device of claim 13, wherein the first material comprises, a silicon wafer, a silicon carbide wafer, an alumina wafer, or a glass substrate, and wherein the first material is different than the second material.

19. The cleaning device of claim 13, wherein the first material comprises any one of a silicone, an acrylate based polymer, an epoxy based polymer, polyethylene terephthalate, or polyimide.

20. The cleaning device of claim 19, wherein the second material comprises any one of a silicone, an acrylate based polymer, an epoxy based polymer, polyethylene terephthalate, or polyimide and an abrasive material dispersed therein.

21. The cleaning device of claim 20, wherein the abrasive material comprises silicon carbide.

22. A cleaning device comprising:
a body including a base and a functional material disposed over the base layer, the functional material comprising unmodified functional material and selected regions of modified functional material, wherein the unmodified functional material provides at least a first function and the selected regions of modified functional material provide at least a second function, wherein the first function is different from the second function; and
wherein the cleaning device is adapted to perform at least the first function and the second function when a probe card contacts the body of the cleaning device during a cleaning cycle.

23. The cleaning device of claim 22, wherein at least a hardness of the selected regions is greater than a hardness of the unmodified functional material.
